(19) United States
(12) Patent Application Publication
(10) Pub. No.: US 2026/0290745 A1
(43) Pub. Date: Sep. 24, 2026

(54) IMAGE GRABBING MAPPING METHOD TO IMPROVE SYSTEM PRODUCTIVITY IN A SYSTEM WITH MULTIPLE ELECTRON BEAMS

(71) Applicant: KLA Corporation, Milpitas, CA (US)

(72) Inventors: Youngjin CHOI, San Jose, CA (US); Sameet K. SHRIYAN, Milpitas, CA (US)

(21) Appl. No.: 19/088,925

(22) Filed: Mar. 24, 2025

(51) Int. Cl. H01J 37/22; G06T 7/00; H01J 37/24; H01J 37/28

(52) U.S. Cl. CPC H01J 37/222; G06T 7/0004; H01J 37/24; H01J 37/28; G06T 2200/24; G06T 2207/10061; G06T 2207/30148; H01J 2237/221

(57) ABSTRACT

A care area on a surface of a workpiece is determined. At least two beamlet sites are used to image the care area. Each of the beamlet sites is an area on the workpiece covered by an electron beamlet. A scanning coverage rate for the care area, a number of beamlet sites in the care area, and/or at least one location of the beamlet sites in the care area is then determined. Instructions are sent to an electron beam source and a beam optics to target the care area with the scanning coverage rate and/or beamlet scanning location.

### FIELD OF THE DISCLOSURE

This disclosure relates to electron beam systems and, more particularly, to image grabbing techniques in an electron beam system.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it maximizes the return-on-investment for a semiconductor manufacturer.

Fabricating semiconductor devices, such as logic and memory devices, typically includes processing a semiconductor wafer using a large number of fabrication processes to form various features and multiple levels of the semiconductor devices. For example, lithography is a semiconductor fabrication process that involves transferring a pattern from a reticle to a photoresist arranged on a semiconductor wafer. Additional examples of semiconductor fabrication processes include, but are not limited to, chemical-mechanical polishing (CMP), etching, deposition, and ion implantation. An arrangement of multiple semiconductor devices fabricated on a single semiconductor wafer may be separated into individual semiconductor devices.

Inspection processes are used at various steps during semiconductor manufacturing to detect defects on wafers to promote higher yield in the manufacturing process and, thus, higher profits. Inspection has always been an important part of fabricating semiconductor devices such as integrated circuits (ICs). However, as the dimensions of semiconductor devices decrease, inspection becomes even more important to the successful manufacture of acceptable semiconductor devices because smaller defects can cause the devices to fail. For instance, as the dimensions of semiconductor devices decrease, detection of defects of decreasing size has become necessary because even relatively small defects may cause unwanted aberrations in the semiconductor devices.

Defect review typically involves re-detecting defects that were detected by an inspection process and generating additional information about the defects at a higher resolution using either a high magnification optical system or a scanning electron microscope (SEM). Defect review is typically performed at discrete locations on specimens where defects have been detected by inspection. The higher resolution data for the defects generated by defect review is more suitable for determining attributes of the defects such as profile, roughness, or more accurate size information.

Metrology processes also are used at various steps during semiconductor manufacturing to monitor and control the process. Metrology processes are different than inspection processes in that, unlike inspection processes in which defects are detected on wafers, metrology processes are used to measure one or more characteristics of the wafers that cannot be determined using existing inspection tools. Metrology processes can be used to measure one or more characteristics of wafers such that the performance of a process can be determined from the one or more characteristics. For example, metrology processes can measure a dimension (e.g., line width, thickness, etc.) of features formed on the wafers during the process. In addition, if the one or more characteristics of the wafers are unacceptable (e.g., out of a predetermined range for the characteristic(s)), the measurements of the one or more characteristics of the wafers may be used to alter one or more parameters of the process such that additional wafers manufactured by the process have acceptable characteristic(s).

Some inspection and metrology processes use systems that generate multiple electron beams. While, using multiple electron beams can increase throughput relative to using a single electron beam, multiple electron beams present their own problems. Systems tend to over-scan a target area (e.g., a care area), which means that a percentage of the beam is outside the target area. This is shown in FIG. 1. The care area 100 in FIG. 1 is shown with shading. Five beamlet sites 101 are used to image most of the care area 100. The beamlet sites 101 are shown with circles. Depending on the care area 100, over-scanning may be more than 60% of the total area of the beamlet sites 101. Thus, more than half of the area of the beamlet sites 101 can be outside of the boundaries of the care area 100. This reduces system throughput. Improved systems and techniques are needed.

### BRIEF SUMMARY OF THE DISCLOSURE

A system is provided in a first embodiment. The system includes an electron beam source that generates an electron beam; a multi-lens array assembly that splits the electron beam into a plurality of electron beamlets; an optical assembly that is configured to independently steer each of the electron beamlets; a stage configured to hold a workpiece in a path of the electron beamlets; a detector configured to receive electrons returned from the workpiece; and a processor in electronic communication with the electron beam source and the beam optics. The processor is configured to determine a care area on a surface of the workpiece; determine a scanning coverage rate for the care area, a number of beamlet sites in the care area, and/or at least one location of the beamlet sites in the care area; and send instructions to the electron beam source and the beam optics to target the care area with the scanning coverage rate and/or beamlet scanning location. The care area is less than an entirety of the surface. At least two beamlet sites are used to image the care area. Each of the beamlet sites is an area on the workpiece covered by one of the electron beamlets.

The processor may determine the scanning coverage rate of the care area. The scanning coverage rate may be 100% of the care area or less than 100% of the care area. The beamlet sites may use only one of the electron beamlets or more than one of the electron beamlets.

The processor may be further configured to determine a high-priority region of the care area and determine the at least one location of the beamlet sites so that the high-priority region is included in the beamlet sites.

If the scanning coverage rate is determined, the processor may be further configured to determine the number of beamlet sites and/or the at least one location of the beamlet sites based on the scanning coverage rate.

The processor can provide a graphic user interface configured to allow placement of the location of the beamlet sites on the care area.

A method is provided in a second embodiment. The method includes determining, using a processor, a care area on a surface of a workpiece. The care area is less than entirety of the surface. At least two beamlet sites are used to image the care area. Each of the beamlet sites is an area on the workpiece covered by one of a plurality of electron beamlets. Using the processor, a scanning coverage rate for the care area, a number of beamlet sites in the care area, and/or at least one location of the beamlet sites in the care area is determined. Instructions are sent to an electron beam source and a beam optics to target the care area with the scanning coverage rate and/or beamlet scanning location.

The method can include generating a plurality of the electron beamlets using an electron beam source that produces an electron beam; directing the electron beamlets with an electron optics configured to independently steer each of the electron beamlets in accordance with the instructions; directing the electron beamlets to the workpiece on a stage; and measuring electrons returned from the workpiece using a detector.

The beamlet sites may use only one of the electron beamlets or more than one of the electron beamlets.

The method can include performing inspection or metrology of the workpiece using images produced with output from the detector.

The method can include determining the scanning coverage rate of the care area using the processor. The scanning coverage rate may be 100% of the care area or less than 100% of the care area.

The method can include determining a high-priority region of the care area using the processor and determining, using the processor, the at least one location of the beamlet sites so that the high-priority region is included in the beamlet sites.

If the method includes determining the scanning coverage rate, the method can include determining the number of beamlet sites and/or the at least one location of the beamlet sites based on the scanning coverage rate using the processor.

The method can include placing the location of the beamlet sites on the care area using a graphic user interface.

A non-transitory computer readable medium storing a program can be configured to instruct a processor to execute the method of the second embodiment.

### DESCRIPTION OF THE DRAWINGS

For a fuller understanding of the nature and objects of the disclosure, reference should be made to the following detailed description taken in conjunction with the accompanying drawings, in which:

FIG. 1 illustrates imaging a care area with a previous technique;

FIG. 2 is a flowchart of a method in accordance with the present disclosure;

FIG. 3 illustrates imaging a care area using an embodiment in accordance with the present disclosure;

FIG. 4 illustrates imaging a care area using an embodiment in accordance with the present disclosure; and

FIG. 5 is a block diagram of a system in accordance with the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

Embodiments disclosed herein optimize scanning operation of beamlets. A system can produce multiple beamlets that are used to image a workpiece. Depending on the scan area size, which can be a care area or other target area, movement and/or placement of the beamlets is determined. Throughput is improved by optimizing the scan of the beamlets. The beamlet scan area and/or locations can be selected for more accurate image analysis. For example, a coverage rate number can be set for a particular recipe. In another example, beamlet locations can be added or removed in a target area, such as a care area. Using fewer beamlet sites during imaging can increase utilization of the system, which increases throughput.

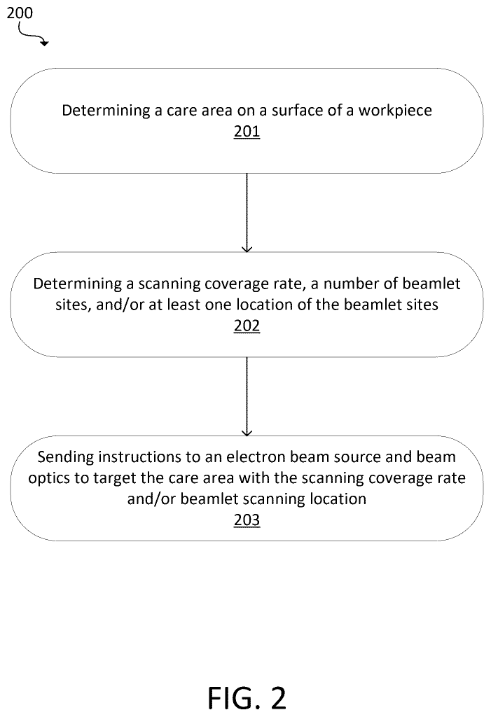

An embodiment of a method 200 is shown in FIG. 2. Some or all of the steps of the method 200 can be performed using a processor. The method 200 may be performed in an inspection or metrology system that generates multiple electron beams. While described with a care area, other target areas also can be used. The term care area is used for simplicity.

At 201, a care area is determined. A size of the care area can vary. For example, a care area may be a square that is 100 μm by 100 μm. This care area is on a surface of a workpiece, such as a semiconductor wafer. Other polygonal shapes are possible. The care area is less than an entirety of a surface of the workpiece. For example, the care area may have a dimension from 10 μm to 900 μm, though other sizes are possible. The care area may be associated with a particular device or structure on the workpiece. A user also can select a care area on the workpiece.

At least two beamlet sites are used to image the care area. A size of the beamlet sites can vary, such as for particular applications. For example, a beamlet site may have dimensions from 9 μm to 15 μm (e.g., 10 μm or 12 μm). Each of the beamlet sites is an area on the workpiece covered by one of the electron beamlets during imaging. Thus, two beamlet sites can be two different beamlets or can be the same beamlet targeting both beamlet sites. Use of two beamlet sites does not necessarily mean that two different beamlets are used during image grabbing. In an instance, the beamlet sites are imaged simultaneously while scanning the care area with the beamlets. The image data can be saved and spread out over a whole image. Each beamlet can cover the its target location (e.g., beamlet site) and then the image data can be combined to determine the whole image.

At 202, a scanning coverage rate for the care area, a number of beamlet sites in the care area, and/or at least one location of the beamlet sites in the care area can be determined. A beamlet site in the care area may be totally contained within the care area or may only partially overlap with the care area. Adjusting the scanning location can provide for a more intense scanning of certain parts of the care area, such as to provide better image quality or to better image an area of high-priority region. A beamlet site also can be removed from the care area to improve scanning efficiency, which may occur if part of the care area is a low-priority region. In an embodiment, the scanning coverage rate for the care area, number of beamlet sites in the care area, and/or at least one location of the beamlet sites is automatically selected. For example, these variables may be selected in response to a size or shape of the care area, a location or size of a high-priority region of the care area, desired throughput, or beamlet availability. This can provide a map of beamlet sites that will be used as part of the image grabbing.

In an example, the system can generate the beamlet sites to cover an entire care area size so as to not miss any of the care area. This may result in extra scanning area outside the care area that is wasted. To save time and reduce extra scanning area, a user or the system can choose the beamlet sites (i.e., remove a site or add more sites) depending on the care area. This may reduce the coverage area by 10%, but the scanning time may be reduced up to 30%, which can be an overall benefit for throughput and cost.

The size of the beamlet sites may change as part of step 202. Each beamlet has its own field of view (FOV). The scanning area can be determined with each beamlet's dimension and location to cover a whole care area without missing any desired parts of the image or any of the image. Each beamlet may have a minimum overlap with other beamlets to detect defects near each boundary area. The minimum overlap dimension or setting may be applied to a whole care area or workpiece.

In an instance, the scanning coverage rate is 100% of the care area. Thus, all of the care area can be covered by the beamlet sites. In another instance, the scanning coverage rate is less than 100% of the care area. A lower coverage rate may be used to avoid low-priority regions of the care area. The priority may depend on device architecture (e.g., structure of the workpiece). A user can set which area is more important or is a hot spot area in the device architecture. Selecting a scanning coverage rate can affect the number and/or placement of the beamlet sites in the care area. In an example, a minimum beamlet number inside a care area is determined based at least partly on the coverage rate, which can be separately determined. The exact coverage rate then can be determined. If the coverage rate is higher than the coverage number, the system can remove one or more of the beamlet sites to improve the coverage rate number.

In an embodiment, a high-priority region of the care area is determined. The high-priority regions may be hot spots based on the device architecture. At least one location of the beamlet sites is determined so that the high-priority region is included in one of the beamlet sites.

In an embodiment, the scanning coverage rate is determined. The scanning coverage rate may be, for example, a percentage of the care area that is imaged using the beamlet sites during image grabbing. This includes determining a number of beamlet sites and/or at least one location of a beamlet site based on the scanning coverage rate. The device architecture is a factor to determine scanning coverage rate because a user may want to focus on the high-priority region. Overall throughput also can be a factor to determine scanning coverage rate because reducing the scanning sites can improve the throughput.

In an embodiment, a user can place the location of the beamlet sites on the care area using a graphic user interface. The user can move the location of one or more beamlet sites. The user also can add or remove beamlet sites. These changes by the user can be manual. When a user creates a recipe to use an inspection system with multiple beams or beamlets, the inspection system may generate the scanning sites to automatically cover 100% of care area. Then, the user can change/optimize the location and/or number of the scanning sites to improve throughput. The system also can change/optimize the location and/or number of the scanning sites to attain a particular scanning coverage rate.

At 203, instructions are sent an electron beam source and a beam optics to target the care area with the scanning coverage rate and/or beamlet scanning locations. Two or more electron beamlets can be generated using an electron beam source. The beamlets can be directed through an electron optics that is configured to independently steer each of the beamlets. The beamlets can be directed to the workpiece on a stage, which can be in a pattern to image the care area. The pattern can include the number of beamlet sites and/or at least one location of the beamlet sites in the care area. Electrons returned from the workpiece can be measured using a detector. Information from the detector can be used to generate an image of the care area on the workpiece. The image can be used in, for example, inspection or metrology applications. Improved throughput during inspection or metrology can improve overall workpiece manufacturing.

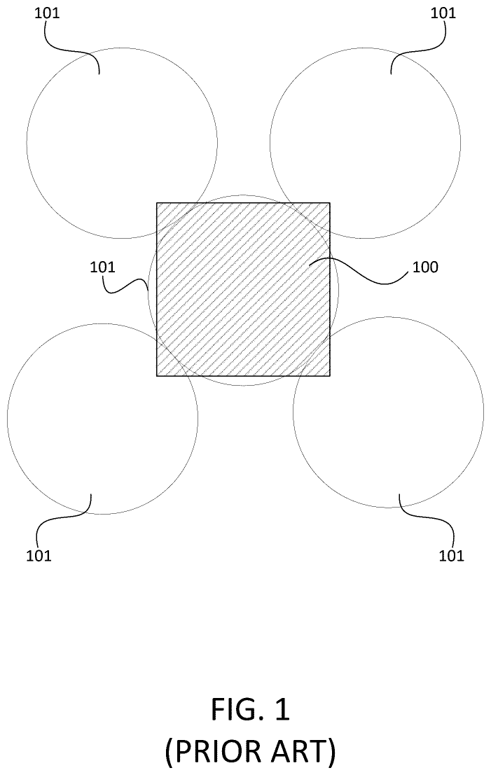

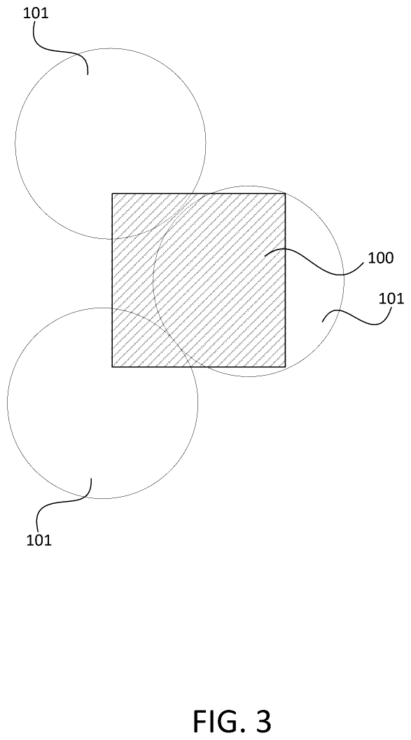

FIG. 3 illustrates imaging an example of the care area 100. Compared to FIG. 1, the beamlet sites 101 are configured differently to image the care area 100. In this instance, a scanning coverage rate for the care area 100, a number of beamlet sites 101 in the care area 100, and/or at least one location of the beamlet sites 101 in the care area 100 was determined. The coverage rate and number of beamlet sites 101 in FIG. 3 is less than that in FIG. 1, which will improve throughput. The position of the beamlet sites 101 can be configured to image a high-priority region of the care area 100. In an example, the part of the care area 100 in FIG. 3 that is not imaged with the care area sites 101 is a low-priority region. If necessary, the beamlet sites 101 can be moved by a user. Also, one or more of the beamlet sites 101 can be removed or at least one additional beamlet site 101 can be added by a user. The system can add or remove one or more beamlet sites 101 based on the scanning coverage rate and high-priority regions while considering a desired throughput or to maximize the throughput.

While the beamlet sites 101 are illustrated in FIG. 3 as circular, the beamlet sites 101 can be other shapes. For example, the beamlet sites 101 can be squares or polygonal. Thus, other shapes are possible.

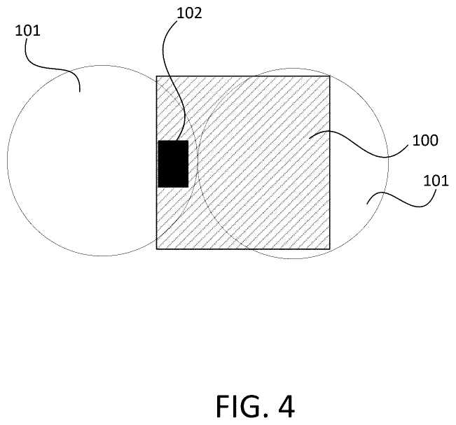

FIG. 4 illustrates imaging an example of the care area 100. The care area 100 in FIG. 4 includes a high-priority region 102 (shown with the shaded box). This is an area of the underlying structure on the workpiece that should be imaged. Another objective in FIG. 4 may be to maximize the coverage area of the care area 100 while only using two beamlet sites 101. Thus, the configuration in FIG. 4 uses one beamlet site 101 to image the high-priority region 102. The second beamlet site 101 is used to increase the coverage area of the care area 100. While only one high-priority region 102 is illustrated, a care area 100 may include two or more high-priority regions 102.

In an instance, a user or design highlights the high-priority region 102. The beamlet sites 101 can be automatically selected to include the high-priority region 102.

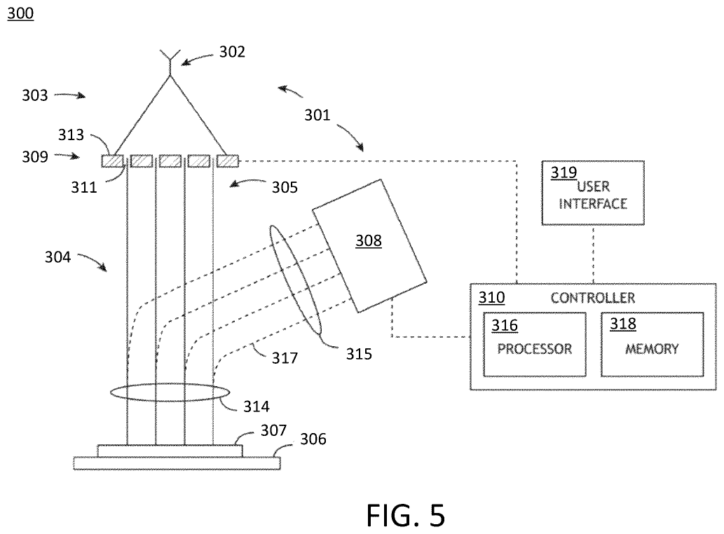

FIG. 5 illustrates a system 300 for performing multi-beam SEM imaging, in accordance with one or more embodiments of the present disclosure. In an embodiment, the system 300 includes a multi-beam scanning electron microscopy (SEM) sub-system 301 and a controller 310. The multi-beam SEM sub-system 301 may include any multi-beam SEM sub-system or multi-beam SEM tool known in the art. For example, the multi-beam SEM sub-system 301 may include, but is not limited to, an electron beam source 303, an optical assembly 304, a stage 306, and a detector 308. The controller 310 may be communicatively coupled to the multi-beam SEM sub-system 301. For example, the controller 310 may be coupled to the output of the detector assembly 308 of the SEM sub-system 301, electron beam source 303, or optical assembly 304. The electron beam source 303 generates multiple beamlets 305. The optical assembly 304 can be configured to independently steer the beamlets 305. The detector 308 receives electrons returned from the workpiece 307 on the stage 306.

In an embodiment, the electron source 303 includes an electron gun 302 and a multi-lens array assembly 309 configured to split an initial illumination beam into multiple electron beamlets 305. For example, the electron gun 302 may include, but is not limited to, a field emission gun (cathode). By way of another example, as shown in FIG. 5, the multi-lens array assembly 309 includes a set of lenses 311 (or “lenslets”) in an array plate 313. In this regard, the set of lenses 311 serve to split the initial illumination electron beam into multiple beamlets 305.

In an embodiment, the multi-beam array assembly 309 is adjustable. For example, the multi-beam array assembly 309 is configured to individually adjust and/or control the focus and/or astigmatism of one or more lenses 311 of the lens array assembly 309. In this embodiment, the individual lenses 311 of the set of lenses of the array assembly 309 may focus each beamlet 305 independently. The optical assembly 304 may include other optical components that steer, focus, or otherwise adjust the beamlets 305.

In an embodiment, the detector 308 simultaneously acquires multiple images (or “sub-images”) of the workpiece 307. In this regard, each of the electron beamlets 305 causes a corresponding electron signal (e.g., secondary electron signal or backscattered electron signal) to form a set of signal beams 317. The signal beams 317 then form a set of corresponding images, or sub-images, at the detector 308. The images acquired by the detector 308 are then transmitted to the controller 310. For example, in the case where the SEM sub-system 301 includes N simultaneously operating beams (e.g., 2 to 200 beams), where N corresponding images are simultaneously acquired by the detector 308, the N images can be analyzed, such as to perform inspection or metrology of the workpiece 307 using one or more of the N images.

The controller 310 may be in electronic communication with the detector 308 (e.g., by one or more transmission media indicated by the line shown in FIG. 5) such that the controller 310 can receive the output acquired by the detector 308. In an embodiment, the controller 310 includes one or more processors 316 and a memory medium 318 (or memory). The one or more processors 316 are configured to execute a set of program instructions maintained in the memory medium 318 for causing the one or more processors 316 to carry out one or more of the various steps described through the present disclosure, such as the method 200.

The processor(s) 316 may be programmed to perform the functions of the method of 200 or other embodiments disclosed herein. The processor(s) 316 can be a hardware device for executing software, particularly software stored in memory. The processor(s) 316 can be any custom made or commercially available processor, a primary processing unit (CPU), an auxiliary processor among several processors associated with a computer, a semiconductor-based microprocessor (in the form of a microchip or chip set), a macro-processor, or generally any device for executing software instructions.

The memory medium 318 is associated with processor(s) 316 and can include any one or a combination of volatile memory elements (e.g., random access memory (RAM, such as DRAM, SRAM, SDRAM, etc.)) and non-volatile memory elements (e.g., ROM, hard drive, tape, CDROM, etc.). Moreover, the memory medium 318 may incorporate electronic, magnetic, optical, and/or other types of storage media. The memory medium 318 can have a distributed architecture where various components are situated remote from one another, but are still accessed by processor(s) 316.

The software in memory medium 318 may include one or more separate programs. The separate programs comprise ordered listings of executable instructions for implementing logical functions to implement the functions of the modules. In an example, the software in memory medium 317 includes the one or more components of the method 200 and is executable on a suitable operating system (O/S).

A user interface 319 is in electronic communication with the controller 310. The user interface 319 can be used to review the care area, determine placement or a number of beamlet sites, or change the placement or number of beamlet sites. The user interface 319 can include a display and user input (e.g., keyboard, mouse, touch screen, etc.).

It is noted that, while the present disclosure focuses on a SEM sub-system 301 that generates multiple electron beams using an electron gun and multi-lens array, this configuration should not be interpreted as a limitation on the scope of the present disclosure. It is recognized that multi-beam sub-system 301 may generate multiple electron beams in any manner known in the art.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A system comprising:
an electron beam source that generates an electron beam;
a multi-lens array assembly that splits the electron beam into a plurality of electron beamlets;
an optical assembly that is configured to independently steer each of the electron beamlets;
a stage configured to hold a workpiece in a path of the electron beamlets;
a detector configured to receive electrons returned from the workpiece; and
a processor in electronic communication with the electron beam source and the beam optics, wherein the processor is configured to:
determine a care area on a surface of the workpiece, wherein the care area is less than an entirety of the surface, wherein at least two beamlet sites are used to image the care area, and wherein each of the beamlet sites is an area on the workpiece covered by one of the electron beamlets;
determine a scanning coverage rate for the care area, a number of beamlet sites in the care area, and/or at least one location of the beamlet sites in the care area; and
send instructions to the electron beam source and the beam optics to target the care area with the scanning coverage rate and/or beamlet scanning location.

2. The system of claim 1, wherein the processor determines the scanning coverage rate of the care area, and wherein the scanning coverage rate is 100% of the care area.

3. The system of claim 1, wherein the processor determines the scanning coverage rate of the care area, and wherein the scanning coverage rate is less than 100% of the care area.

4. The system of claim 1, wherein the beamlet sites use only one of the electron beamlets.

5. The system of claim 1, wherein the beamlet sites use more than one of the electron beamlets.

6. The system of claim 1, wherein the processor is further configured to:
determine a high-priority region of the care area; and
determine the at least one location of the beamlet sites so that the high-priority region is included in the beamlet sites.

7. The system of claim 1, wherein the scanning coverage rate is determined, and wherein the processor is further configured to determine the number of beamlet sites and/or the at least one location of the beamlet sites based on the scanning coverage rate.

8. The system of claim 1, wherein the processor provides a graphic user interface configured to allow placement of the location of the beamlet sites on the care area.

9. A method comprising:
determining, using a processor, a care area on a surface of a workpiece, wherein the care area is less than an entirety of the surface, wherein at least two beamlet sites are used to image the care area, and wherein each of the beamlet sites is an area on the workpiece covered by one of a plurality of electron beamlets;
determining, using the processor, a scanning coverage rate for the care area, a number of beamlet sites in the care area, and/or at least one location of the beamlet sites in the care area; and
sending instructions to an electron beam source and a beam optics to target the care area with the scanning coverage rate and/or beamlet scanning location.

10. The method of claim 9, further comprising:
generating a plurality of the electron beamlets using an electron beam source that produces an electron beam;
directing the electron beamlets with an electron optics configured to independently steer each of the electron beamlets in accordance with the instructions;
directing the electron beamlets to the workpiece on a stage; and
measuring electrons returned from the workpiece using a detector.

11. The method of claim 10, wherein the beamlet sites use only one of the electron beamlets.

12. The method of claim 10, wherein the beamlet sites use more than one of the electron beamlets.

13. The method of claim 10, further comprising performing inspection or metrology of the workpiece using images produced with output from the detector.

14. The method of claim 9, wherein the method includes determining the scanning coverage rate of the care area using the processor, and wherein the scanning coverage rate is 100% of the care area.

15. The method of claim 9, wherein the method includes determining the scanning coverage rate of the care area using the processor, and wherein the scanning coverage rate is less than 100% of the care area.

16. The method of claim 9, further comprising:
determining a high-priority region of the care area using the processor; and
determining, using the processor, the at least one location of the beamlet sites so that the high-priority region is included in the beamlet sites.

17. The method of claim 9, wherein the method includes determining the scanning coverage rate, and further comprising determining the number of beamlet sites and/or the at least one location of the beamlet sites based on the scanning coverage rate using the processor.

18. The method of claim 9, further comprising placing the location of the beamlet sites on the care area using a graphic user interface.

19. A non-transitory computer readable medium storing a program configured to instruct a processor to execute the method of claim 9.
